(19) United States
(12) Patent Application Publication
(10) Pub. No.: US 2022/0367651 A1
(43) Pub. Date: Nov. 17, 2022

(54) STACKED-GATE NON-VOLATILE MEMORY CELL

(71) Applicant: eMemory Technology Inc., Hsin-Chu (TW)

(72) Inventor: Te-Hsun HSU, Hsinchu County (TW)

(21) Appl. No.: 17/673,831

(22) Filed: Feb. 17, 2022

Related U.S. Application Data
(60) Provisional application No. 63/187,422, filed on May 12, 2021.

(51) Int. Cl. H01L 29/423; H01L 29/788; H01L 21/28; H01L 29/66

(52) U.S. Cl. CPC H01L 29/42324; H01L 29/7883; H01L 29/40114; H01L 29/66825

(57) ABSTRACT

A stacked-gate non-volatile memory cell includes a semiconductor substrate, a floating gate, a first spacer, a control gate, a second spacer, a first doped region and a second doped region. The floating gate is formed over the semiconductor substrate. The first spacer is contacted with a sidewall of the floating gate. The control gate is formed on a top side and a lateral side of the floating gate. The control gate is not contacted with the floating gate. The second spacer is contacted with a sidewall of the control gate. The first doped region and the second doped region are formed in the surface of the semiconductor substrate, and respectively located at two sides of the floating gate.

This application claims the benefit of U.S. provisional application Ser. No. 63/187,422, filed May 12, 2021, the subject matter of which is incorporated herein by reference.

### FIELD OF THE INVENTION

The present invention relates to a non-volatile memory cell, and more particularly to a stacked-gate non-volatile memory cell.

### BACKGROUND OF THE INVENTION

FIG. 1 is a schematic cross-sectional view illustrating the structure of a conventional double-poly non-volatile memory cell. The double-poly non-volatile memory cell 100 is a floating-gate transistor. The floating-gate transistor is a P-type floating-gate transistor or an N-type floating-gate transistor.

As shown in FIG. 1, this double-poly non-volatile memory cell 100 comprises two stacked and separated gates. The upper gate is a control gate 150, which is connected to a control line C. The lower gate is a floating gate 140. In addition, a source doped region 130 and a drain doped region 120 are constructed in a substrate 110. The source doped region 130 is connected to a source line S. The drain doped region 120 is connected to a drain line D.

Generally, by providing proper bias voltages to the drain line D, the source line S and the control line S, the double-poly non-volatile memory cell 100 can be selectively subjected to a program operation, an erase operation or a read operation.

In case that hot carriers are controlled to be injected into the floating gate 140 through a channel region of the floating-gate transistor during the program operation, a great number of hot carriers are accumulated in the floating gate 140. Under this circumstance, the double-poly non-volatile memory cell 100 is considered to be in a first storage state (e.g., “0” state). In case that hot carriers are not injected into the floating gate 140 during the program operation, no hot carriers are accumulated in the floating gate 140. Under this circumstance, the double-poly non-volatile memory cell 100 is considered to be in a second storage state (e.g., “1” state). The region between the source doped region 130 and the drain doped region 120 is the channel region. For example, the hot carriers are electrons.

During the erase operation, hot carriers are controlled to be ejected from the floating gate 140 of the floating-gate transistor. Consequently, no hot carriers are accumulated in the floating gate 140.

During the read operation, the double-poly non-volatile memory cell 100 is determined to be in the first storage state or the second storage state according to the magnitude of a read current that is generated between the source line S and the drain line D.

Generally, in the conventional double-poly non-volatile memory cell 100, the control gate 150 is directly located over the floating gate 140. Due to this structural design, the coupling ratio of the control gate 150 is low. Because of the low coupling ratio, some drawbacks occur. For example, during the program operation and the erase operation, it is necessary to provide a higher voltage to the control line C in order to inject/reject the hot carriers into/from the floating gate 140.

### SUMMARY OF THE INVENTION

The present invention provides a stacked-gate non-volatile memory cell. In the stacked-gate non-volatile memory cell, a control gate is formed on the top side and the lateral side of a floating gate. That is, the control gate is not contacted with the floating gate, and the control gate covers the floating gate. Consequently, the coupling ratio of the control gate is higher, and the program operation and the erase operation can be performed more easily.

An embodiment of the present invention provides a stacked-gate non-volatile memory cell. The stacked-gate non-volatile memory cell includes a semiconductor substrate, a gate structure, a first doped region, a second doped region, a first silicide layer, a second silicide layer, a resist protection oxide layer, a first insulation material layer, a conductive material layer, a second insulation material layer, a second spacer, a contact etch stop layer, an interlayer dielectric layer, a first contact hole, a second contact hole and a third contact hole. The gate structure is formed on a surface of the semiconductor substrate. The gate structure includes a gate dielectric layer, a gate layer and a first spacer. The gate dielectric layer is formed on the surface of the semiconductor substrate. The gate layer is formed on the gate dielectric layer. The first spacer is contacted with a sidewall of a gate dielectric layer and a sidewall of the gate layer. The first doped region and the second doped region are formed under the surface of the semiconductor substrate, and respectively located at two sides of the gate structure. The first silicide layer is contacted with the first doped region. The second silicide layer is contacted with the second doped region. The resist protection oxide layer covers the gate structure. The first insulation material layer covers the resist protection oxide layer. The conductive material layer covers the first insulation material layer. The second insulation material layer covers the conductive material layer. The second spacer is located over the first insulation material layer and contacted with a sidewall of the conductive material layer and a sidewall of the second insulation material layer. The contact etch stop layer covers the second insulation material layer, the second spacer, the first silicide layer and the second silicide layer. The interlayer dielectric layer covers the contact etch stop layer. The first contact hole is located over the first silicide layer. A first conductive metal structure is filled into the first contact hole. The first conductive metal structure is contacted with the first silicide layer. The second contact hole is located over the second silicide layer. A second conductive metal structure is filled into the second contact hole. The second conductive metal structure is contacted with the second silicide layer. The third contact hole is located over the conductive material layer. A third conductive metal structure is filled into the third contact hole. The third conductive metal structure is contacted with the conductive material layer.

Another embodiment of the present invention provides a stacked-gate non-volatile memory cell. The stacked-gate non-volatile memory cell includes a semiconductor substrate, a floating gate, a first spacer, a control gate, a second spacer, a first doped region and a second doped region. The floating gate is formed over the semiconductor substrate. The first spacer is contacted with a sidewall of the floating gate. The control gate is formed on a top side and a lateral side of the floating gate. The control gate is not directly contacted with the floating gate. The second spacer is contacted with a sidewall of the control gate. The first doped region and the second doped region are formed under the surface of the semiconductor substrate, and respectively located at two sides of the floating gate.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 (prior art) is a schematic cross-sectional view illustrating the structure of a conventional double-poly non-volatile memory cell;

FIGS. 2A-2I are schematic cross-sectional views illustrating the steps of a method for manufacturing a stacked-gate non-volatile memory cell according to an embodiment of the present invention;

FIG. 3 is schematic circuit diagram illustrating the electronic symbol of the stacked-gate non-volatile memory cell according to the embodiment of the present invention;

FIG. 4 is a schematic circuit diagram illustrating a memory cell array according to an embodiment of the present invention;

FIG. 5A is a schematic circuit diagram illustrating the associated bias voltage for performing a program operation on the memory cell array as shown in FIG. 4;

FIG. 5B is a schematic circuit diagram illustrating the associated bias voltage for performing another program operation on the memory cell array as shown in FIG. 4; and

FIG. 5C is a schematic circuit diagram illustrating the associated bias voltage for performing an erase operation on the memory cell array as shown in FIG. 4.

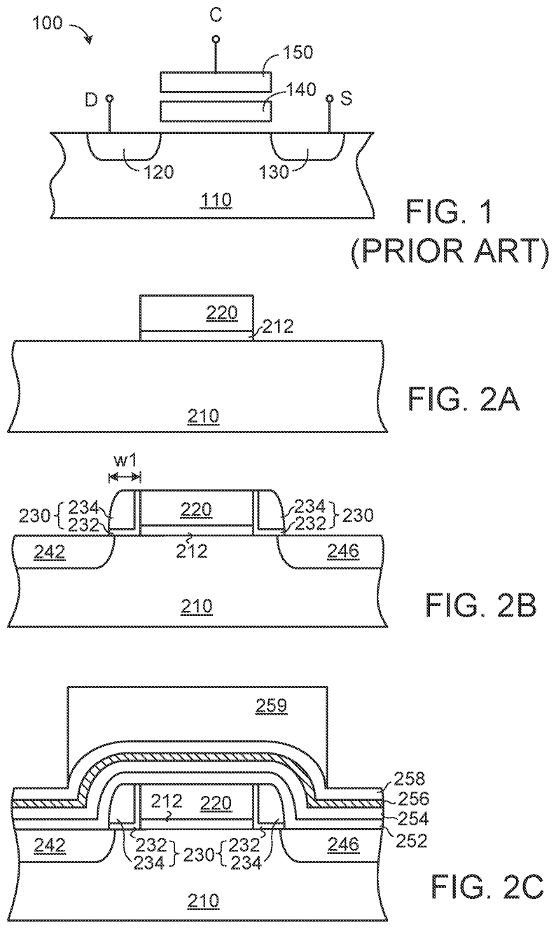

### DETAILED DESCRIPTION OF PREFERRED EMBODIMENTS

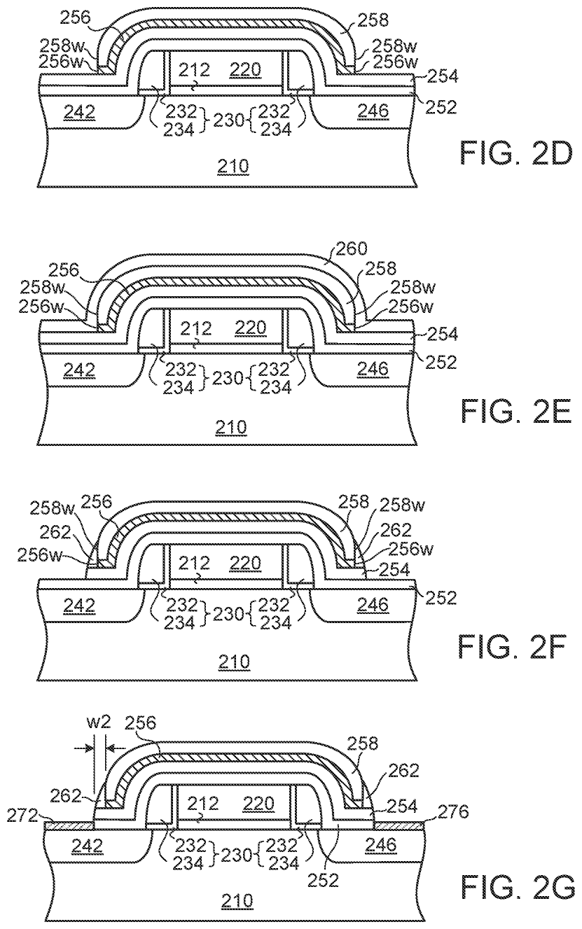

FIGS. 2A-2I are schematic cross-sectional views illustrating the steps of a method for manufacturing a stacked-gate non-volatile memory cell according to an embodiment of the present invention.

Please refer to FIG. 2A. Firstly, a gate dielectric layer 212 and a polysilicon gate layer 220 are formed on a semiconductor substrate 210. The gate dielectric layer 212 is contacted with a surface of the semiconductor substrate 210. The polysilicon gate layer 220 is contacted with the gate dielectric layer 212.

Please refer to FIG. 2B. Then, a spacer 230 is formed on and contacted with the surface of the semiconductor substrate 210. The spacer 230 is arranged around the gate dielectric layer 212 and the polysilicon gate layer 220. Consequently, a gate structure is formed. In other words, the gate structure comprises the gate dielectric layer 212, the polysilicon gate layer 220 and the spacer 230. The spacer 230 is contacted with the sidewall of the gate dielectric layer 212 and the sidewall of the polysilicon gate layer 220. The width w1 of the spacer 230 is approximately in the range between 30 nm and 50 nm.

The spacer 230 comprises a silicon oxide layer 232 and a silicon nitride (SiN) layer 234. The silicon oxide layer 232 is contacted with the surface of the semiconductor substrate 210. In addition, the silicon oxide layer 232 is contacted with the sidewall of the gate dielectric layer 212 and the sidewall of the polysilicon gate layer 220. The silicon nitride layer 234 covers the silicon oxide layer 232. Generally, the process of forming the gate structure is a partial process of a standard logic process. The detailed process of forming the gate structure is not redundantly described herein.

After the gate structure is formed, a doping process is performed. Consequently, two doped regions 242 and 246 are formed in the positions under the surface of the semiconductor substrate 210 and respectively located at two sides of the gate structure.

Please refer to FIG. 2C. Then, a resist protection oxide (RPO) layer 252, a first insulation material layer 254, a conductive material layer 256 and a second insulation material layer 258 are sequentially formed over the resulting structure of FIG. 2B. A photoresist layer 259 is directly formed over the spacer 230 and the polysilicon gate layer 220. Moreover, the vertical projection area of the photoresist layer 259 is larger than the vertical projection area of the gate structure.

Please refer to FIG. 2C again. The resist protection oxide layer 252 covers the surface of the semiconductor substrate 210, the spacer 230 and the polysilicon gate layer 220. The first insulation material layer 254 covers the resist protection oxide layer 252. The conductive material layer 256 covers the first insulation material layer 254. The second insulation material layer 258 covers the conductive material layer 256. The photoresist layer 259 is contacted with the second insulation material layer 258. In this embodiment, the first insulation material layer 254 and the second insulation material layer 258 are silicon nitride (SiN) layers, and the conductive material layer 256 is a titanium nitride (TiN) layer. Moreover, the polysilicon gate layer 220 is used as a floating gate of a floating-gate transistor, and the conductive material layer 256 is used as a control gate of the floating-gate transistor.

Then, two etching processes are performed by using the photoresist layer 259 as an etching mask. Consequently, the exposed portions of the second insulation material layer 258 and the conductive material layer 256 are removed sequentially. Please refer to FIG. 2D. After the etching processes are completed, a sidewall 258w of the second insulation material layer 258 and a sidewall 256w of the conductive material layer 256 are exposed.

Please refer to FIG. 2E. Then, a third insulation material layer 260 is formed to cover the first insulation material layer 254 and the second insulation material layer 258. Moreover, the third insulation material layer 260 is contacted with the sidewall 256w of the conductive material layer 256 and the sidewall 258w of the second insulation material layer 258.

After an etching process is performed, portions of the third insulation material layer 260 and the first insulation material layer 254 are removed. Please refer to FIG. 2F. After the etching process is completed, the resistor protection oxide layer 252 is exposed, and the remaining portion of the third insulation material layer 260 is served as another spacer 262. The spacer 262 is located over the first insulation material layer 254. Moreover, the spacer 262 is contacted with the sidewall 256w of the conductive material layer 256 and the sidewall 258w of the second insulation material layer 258. Moreover, the third insulation material layer 260 is a silicon nitride (SiN) layer, and the spacer 262 is a silicon nitride (SiN) spacer.

After an etching process is performed, the exposed portion of the resist protection oxide layer 252 is removed, and the two doped regions 242 and 246 are exposed. Please refer to FIG. 2G. Then, two silicide layers 272 and 276 are formed on the surfaces of the two doped regions 242 and 246, respectively. Moreover, the width w2 of the spacer 262 is approximately in the range between 5 nm and 20 nm. In other words, the width w2 of the spacer 262 is smaller than the width w1 of the spacer 230.

Please refer to FIG. 2H. Then, a contact etch stop (CESL) layer 280 is formed to cover the second insulation material layer 258, the spacer 262 and the two silicide layers 272 and 276. Then, an interlayer dielectric (ILD) layer 290 is formed to cover the contact etch stop layer 280.

Please refer to FIG. 2I. After an etching process is performed, three contact holes are formed, and conductive metal structures 292, 296 and 298 are filled into the corresponding contact holes. The conductive metal structure 292 is contacted with the silicide layer 272 and used as a first drain/source terminal. The conductive metal 296 is contacted with the silicide layer 276 and used as a second drain/source terminal. The conductive metal 298 is contacted with the conductive material layer 256 and used as a control gate terminal.

Generally, the resulting structure as shown in FIG. 2I is the stacked-gate non-volatile memory cell 200. The stacked-gate non-volatile memory cell 200 is a floating-gate transistor. In the stacked-gate non-volatile memory cell 200, the gate structure is formed on the surface of the semiconductor substrate 210. The gate structure comprises the gate dielectric layer 212, the polysilicon gate layer 220 and the spacer 230. The gate dielectric layer 212 is formed on the surface of the semiconductor substrate 210. The polysilicon gate layer 220 is formed on the gate dielectric layer 212. The spacer 230 is contacted with the sidewall of the gate dielectric layer 212 and the sidewall of the polysilicon gate layer 220.

The doped regions 242 and 246 are formed in the surface of the semiconductor substrate 210 and respectively located at two sides of the gate structure. The silicide layers 272 and 276 are contacted with the doped regions 242 and 246, respectively.

The resist protection oxide layer 252 covers the gate structure. The first insulation material layer 254 covers the resist protection oxide layer 252. The conductive material layer 256 covers the first insulation material layer 254. The second insulation material layer 258 covers the conductive material layer 256. The spacer 262 is located over the first insulation material layer 254. Moreover, the spacer 262 is contacted with the sidewall of the conductive material layer 256 and the sidewall of the second insulation material layer 258.

The contact etch stop layer 280 covers the second insulation material layer 258, the spacer 262 and the silicide layers 272 and 276. Consequently, at two sides of the gate structure, the spacer 262 is contacted between the sidewall 256w of the conductive material layer 256 and the contact etch stop layer 280, and the spacer 262 is contacted between the sidewall 258w of the of the second insulation material layer 258 and the contact etch stop layer 280. The interlayer dielectric layer 290 covers the contact etch stop layer 280.

The three contact holes are located over the silicide layer 272, the silicide layer 276 and the conductive material layer 256, respectively. The conductive metal structure 292 is filled into the corresponding contact hole and contacted with the silicide layer 272. The conductive metal structure 296 is filled into the corresponding contact hole and contacted with the silicide layer 276. The conductive metal structure 298 is filled into the corresponding contact hole and contacted with the conductive material layer 256.

In an embodiment, the floating-gate transistor is a P-type floating-gate transistor or an N-type floating-gate transistor. For example, in case that the non-volatile memory cell 200 is the N-type floating-gate transistor, the doped regions 242 and 246 are N-type doped regions, and the semiconductor substrate 210 is a P-type semiconductor substrate. Alternatively, the semiconductor substrate 210 is a semiconductor substrate with a P-well region, and the N-type doped regions 242 and 246 are formed on the surface of the P-well region. In case that the non-volatile memory cell 200 is the P-type floating-gate transistor, the doped regions 242 and 246 are P-type doped regions, and the semiconductor substrate 210 is an N-type semiconductor substrate. Alternatively, the semiconductor substrate 210 is a semiconductor substrate with an N-well region, and P-type doped regions 242 and 246 are formed on the surface of the N-well region.

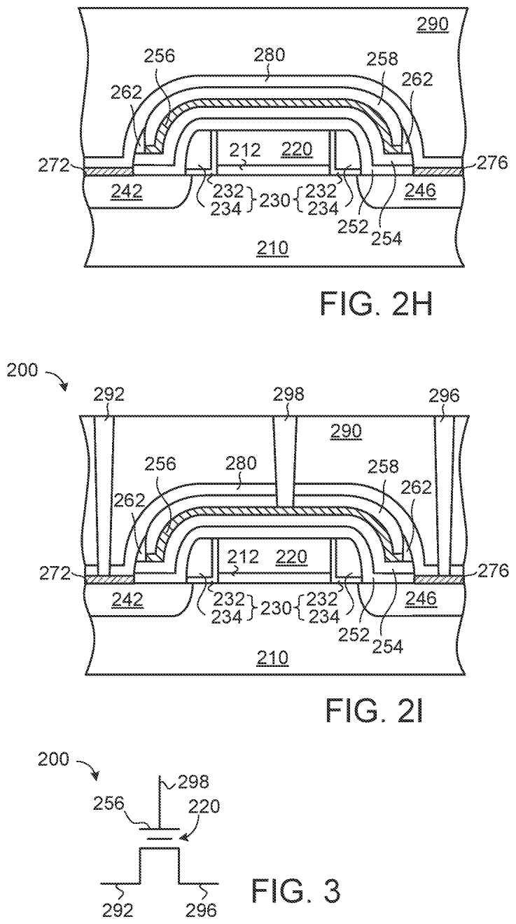

FIG. 3 is schematic circuit diagram illustrating the electronic symbol of the stacked-gate non-volatile memory cell according to the embodiment of the present invention. For example, the stacked-gate non-volatile memory cell 200 is an N-type floating-gate transistor, the polysilicon gate layer 220 is a floating gate, and the conductive material layer 256 is a control gate.

Moreover, the conductive metal structures 298, 292 and 296 are the control gate terminal, the first drain/source terminal and the second drain/source terminal of the N-type floating-gate transistor, respectively.

From the above descriptions, the present invention provides the stacked-gate non-volatile memory cell 200. In the stacked-gate non-volatile memory cell 200, the conductive material layer 256 covers the top sides of the polysilicon gate layer 220 and the spacer 230. In other words, the conductive material layer 256 is not contacted with the polysilicon gate layer 220. More especially, the conductive material layer 256 is formed on the top side and the lateral side of the polysilicon gate layer 220. Since the conductive material layer 256 covers the polysilicon gate layer 220, the coupling ratio of the control gate is higher. Consequently, the program operation and the erase operation can be performed more easily.

As mentioned above, the conductive material layer 256 covers the polysilicon gate layer 220 and the spacer 230. If the conductive material layer 256 is contacted with the conductive metal structure 292 or the silicide layers 272 during the manufacturing process, and if the conductive material layer 256 is contacted with the conductive metal structure 296 or the silicide layers 276 during the manufacturing process, the stacked-gate non-volatile memory cell 200 cannot be operated normally. In order to prevent the conductive material layer 256 from being contacted with the conductive metal structures 292, 296 and silicide layers 272, 276 during the manufacturing process, the stacked-gate non-volatile memory cell 200 is additionally equipped with the spacer 262 at two sides of the gate structure, respectively. The spacer 262 is contacted with the sidewall of the conductive material layer 256, and at each side of the gate structure, the spacer 262 is contacted between the conductive material layer 256 and the contact etch stop layer 280. Consequently, the conductive material layer 256 cannot be contacted with the conductive metal structures 292, 296 and silicide layers 272, 276. In other words, the stacked-gate non-volatile memory cell 200 comprises two spacers 230 and 262. The sidewall of the polysilicon gate layer 220 is contacted with the spacer 230, and the sidewall of the conductive material layer 256 is contacted with the spacer 262.

The present invention further provides a memory cell array. The memory cell array comprises plural stacked-gate non-volatile memory cells 200 with the same configuration. Moreover, a program operation, an erase operation or a read operation can be selectively performed on specified memory cells of the memory cell array.

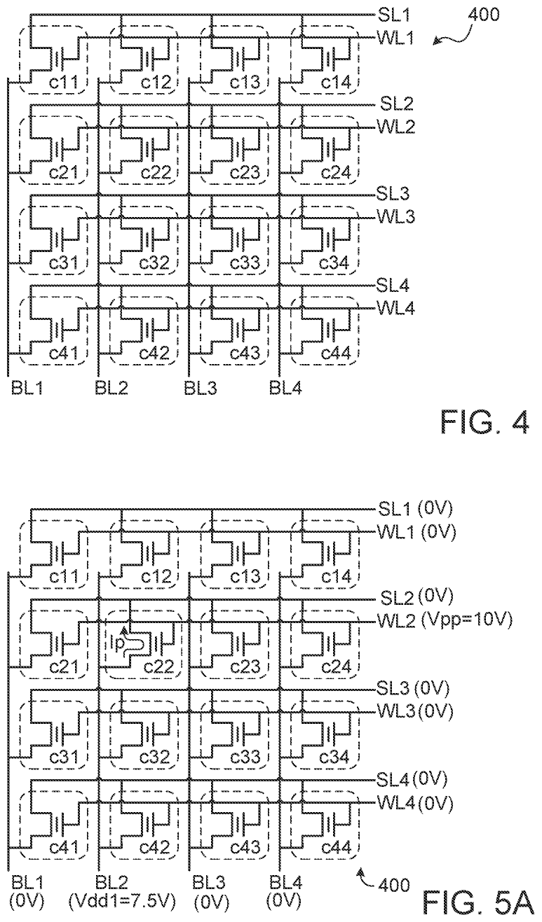

FIG. 4 is a schematic circuit diagram illustrating a memory cell array according to an embodiment of the present invention. As shown in FIG. 4, the memory cell array 400 comprises 16 memory cells c11˜c44, which are arranged in a 4×4 array. The memory cell array 400 is connected with bit lines BL1˜BL4, word lines WL1˜WL4 and source lines SL1˜SL4. Each of the memory cell c11˜c44 comprises a floating-gate transistor. The structure of each of the memory cells c11˜c44 is similar to the stacked-gate non-volatile memory cell of the present invention. Consequently, only the connecting relationships between the memory cells c11˜c44 will be described as follows. The structure of each memory cell is not redundantly described herein.

In the four memory cells c11˜14 of the first row, the control gates of the four floating-gate transistors are all connected with the word line WL1, the first drain/source terminals of the four floating-gate transistors are all connected with the source line SL1, and the second drain/source terminals of the four floating-gate transistors are respectively connected with the corresponding bit lines BL1˜BL4.

In the four memory cells c21˜24 of the second row, the control gates of the four floating-gate transistors are all connected with the word line WL2, the first drain/source terminals of the four floating-gate transistors are all connected with the source line SL2, and the second drain/source terminals of the four floating-gate transistors are respectively connected with the corresponding bit lines BL1˜BL4.

In the four memory cells c31˜34 of the third row, the control gates of the four floating-gate transistors are all connected with the word line WL3, the first drain/source terminals of the four floating-gate transistors are all connected with the source line SL3, and the second drain/source terminals of the four floating-gate transistors are respectively connected with the corresponding bit lines BL1˜BL4.

In the four memory cells c41˜44 of the fourth row, the control gates of the four floating-gate transistors are all connected with the word line WL4, the first drain/source terminals of the four floating-gate transistors are all connected with the source line SL4, and the second drain/source terminals of the four floating-gate transistors are respectively connected with the corresponding bit lines BL1˜BL4.

By providing proper bias voltages to the source lines SL1˜SL4, the bit lines BL1˜BL4 and the word lines WL1˜WL4. Moreover, specified memory cells of the memory cell array 400 can be selectively subjected to a program operation, an erase operation or a read operation.

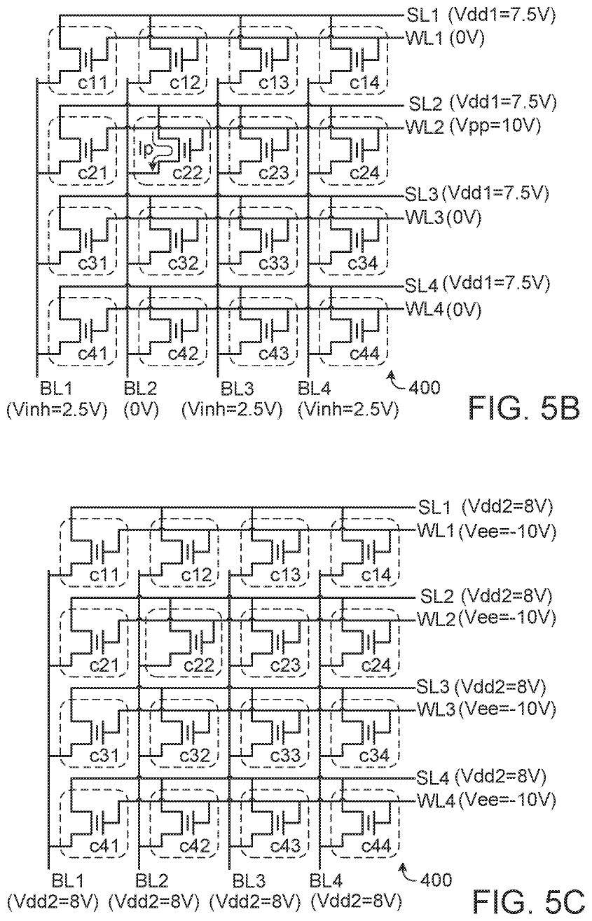

FIG. 5A is a schematic circuit diagram illustrating the associated bias voltage for performing a program operation on the memory cell array as shown in FIG. 4. While the program operation is performed, the word lines

WL1, WL3 and WL4 receive a ground voltage (0V), the word line WL2 receives a program voltage Vpp, the source lines SL1˜SL4 receive the ground voltage (0V), the bit lines BL1, BL3 and BL4 receive the ground voltage (0V), and the bit line BL2 receives a supply voltage Vdd1. For example, the program voltage Vpp is 10V, and the supply voltage Vdd1 is 7.5V. In addition, all of the body terminals (not shown) of the floating-gate transistors in the memory cell array 400 receive the ground voltage (0V). Meanwhile, in the memory cell array 400, the non-volatile memory cell c22 is a selected memory cell, and the other non-volatile memory cells are unselected memory cells.

Consequently, the floating-gate transistor of the non-volatile memory cell c22 is turned on, and a program current Ip is generated. The program current Ip flows from the bit line BL2 to the source line SL2. When the program current Ip flows through the channel region of the floating-gate transistor, a channel hot electron injection effect is generated. Consequently, hot carriers are injected into the floating gate. When a great number of hot carriers are accumulated in the floating gate, the selected memory cell is considered to be in a first storage state (e.g., “0” state). Since the unselected memory cells in the memory cell array 400 do not generate the program current, the unselected memory cells cannot be programmed to the first storage state.

In case that hot carriers are not injected into the floating gate during the program operation, no hot carriers are accumulated in the floating gate. Under this circumstance, the selected memory cell is considered to be in a second storage state (e.g., “1” state). For example, the hot carriers are electrons.

FIG. 5B is a schematic circuit diagram illustrating the associated bias voltage for performing another program operation on the memory cell array as shown in FIG. 4. While the program operation is performed, the word lines WL1, WL3 and WL4 receive a ground voltage (0V), the word line WL2 receives a program voltage Vpp, the source lines SL1˜SL4 receive a supply voltage Vdd1, the bit line BL2 receives the ground voltage (0V), and the bit lines BL1, BL3 and BL4 receive an inhibit voltage Vinh. For example, the program voltage Vpp is 10V, the supply voltage Vdd1 is 7.5V, and the inhibit voltage Vinh is 2.5V. In addition, all of the body terminals (not shown) of the floating-gate transistors in the memory cell array 400 receive the ground voltage (0V). Meanwhile, in the memory cell array 400, the non-volatile memory cell c22 is a selected memory cell, and the other non-volatile memory cells are unselected memory cells.

Consequently, the floating-gate transistor of the non-volatile memory cell c22 is turned on, and a program current Ip is generated. The program current Ip flows from the bit line BL2 to the source line SL2. When the program current Ip flows through the channel region of the floating-gate transistor, a channel hot electron injection effect is generated. Consequently, hot carriers are injected into the floating gate. When a great number of hot carriers are accumulated in the floating gate, the selected memory cell is considered to be in a first storage state (e.g., “0” state). Since the unselected memory cells in the memory cell array 400 do not generate the program current, the unselected memory cells cannot be programmed to the first storage state.

In case that hot carriers are not injected into the floating gate during the program operation, no hot carriers are accumulated in the floating gate. Under this circumstance, the selected memory cell is considered to be in a second storage state (e.g., “1” state). For example, the hot carriers are electrons.

FIG. 5C is a schematic circuit diagram illustrating the associated bias voltage for performing an erase operation on the memory cell array as shown in FIG. 4. While the erase operation is performed, the word lines WL1˜WL4 receive an erase voltage Vee, the source lines SL1˜SL4 receive a supply voltage Vdd2, and the bit lines BL1˜BL4 receive the supply voltage Vdd2. For example, the erase voltage Vee is −10V, and the supply voltage

Vdd2 is 8V. In addition, all of the body terminals (not shown) of the floating-gate transistors in the memory cell array 400 receive the supply voltage Vdd2. Meanwhile, all of the non-volatile memory cells c11˜c44 in the memory cell array 400 generate a Fowler-Nordheim (FN) tunneling effect.

Consequently, the hot carriers are ejected from the floating gates.

From the above descriptions, an embodiment of the present invention provides the stacked-gate non-volatile memory cell 200. In the stacked-gat non-volatile memory cell 200, the conductive material layer 256 covers the top sides of the polysilicon gate layer 220 and the spacer 230. Consequently, the coupling ratio of the control gate is higher, and the program operation and the erase operation can be performed more easily.

In the above embodiments, the first insulation material layer 254 and the second insulation material layer 258 are silicon nitride layers. It is noted that the material of the insulation material layers may be made of any other appropriate material such as silicon dioxide. Similarly, the spacers 230 and 262 can be made of any other appropriate material such as silicon dioxide. Moreover, the conductive material layer 256 is not restricted to the titanium nitride layer. For example, in another embodiment, the conductive material layer 256 is made of titanium.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A stacked-gate non-volatile memory cell, comprising:
a semiconductor substrate;
a gate structure formed on a surface of the semiconductor substrate, and comprising a gate dielectric layer, a gate layer and a first spacer, wherein the gate dielectric layer is formed on the surface of the semiconductor substrate, the gate layer is formed on the gate dielectric layer, and the first spacer is contacted with a sidewall of a gate dielectric layer and a sidewall of the gate layer;
a first doped region and a second doped region formed under the surface of the semiconductor substrate, and respectively located at two sides of the gate structure;
a first silicide layer contacted with the first doped region;
a second silicide layer contacted with the second doped region;
a resist protection oxide layer covering the gate structure;
a first insulation material layer covering the resist protection oxide layer;
a conductive material layer covering the first insulation material layer;
a second insulation material layer covering the conductive material layer;
a second spacer located over the first insulation material layer, and contacted with a sidewall of the conductive material layer and a sidewall of the second insulation material layer;
a contact etch stop layer covering the second insulation material layer, the second spacer, the first silicide layer and the second silicide layer;
an interlayer dielectric layer covering the contact etch stop layer;
a first contact hole located over the first silicide layer, wherein a first conductive metal structure is filled into the first contact hole, and the first conductive metal structure is contacted with the first silicide layer;
a second contact hole located over the second silicide layer, wherein a second conductive metal structure is filled into the second contact hole, and the second conductive metal structure is contacted with the second silicide layer; and
a third contact hole located over the conductive material layer, wherein a third conductive metal structure is filled into the third contact hole, and the third conductive metal structure is contacted with the conductive material layer.

2. The stacked-gate non-volatile memory cell as claimed in claim 1, wherein the first spacer comprises a silicon oxide layer and a silicon nitride layer, wherein the silicon oxide layer is contacted with the surface of the semiconductor substrate, the silicon oxide layer is contacted with the sidewall of the gate dielectric layer and the sidewall of the gate layer, and the silicon nitride layer covers the silicon oxide layer.

3. The stacked-gate non-volatile memory cell as claimed in claim 1, wherein the gate layer is a polysilicon gate layer.

4. The stacked-gate non-volatile memory cell as claimed in claim 1, wherein the conductive material layer is not directly contacted with the gate layer, and the conductive material layer is formed on a top side and a lateral side of the gate layer.

5. The stacked-gate non-volatile memory cell as claimed in claim 1, wherein the conductive material layer is a titanium nitride layer.

6. The stacked-gate non-volatile memory cell as claimed in claim 1, wherein the first insulation material layer and the second insulation material layer are silicon nitride layers.

7. The stacked-gate non-volatile memory cell as claimed in claim 1, wherein the second spacer is a silicon nitride spacer.

8. The stacked-gate non-volatile memory cell as claimed in claim 1, wherein a width of the first spacer is in a range between 30 nm and 50 nm, and a width of the second spacer is in a range between 5 nm and 20 nm.

9. A stacked-gate non-volatile memory cell, comprising:
a semiconductor substrate;
a floating gate formed over the semiconductor substrate;
a first spacer contacted with a sidewall of the floating gate;
a control gate formed on a top side and a lateral side of the floating gate, wherein the control gate is not directly contacted with the floating gate;
a second spacer contacted with a sidewall of the control gate; and
a first doped region and a second doped region formed under the surface of the semiconductor substrate, and respectively located at two sides of the floating gate.

10. The stacked-gate non-volatile memory cell as claimed in claim 9, wherein the first spacer comprises a silicon oxide layer and a silicon nitride layer, wherein the silicon oxide layer is contacted with the surface of the semiconductor substrate, the silicon oxide layer is contacted with the sidewall of the floating gate, and the silicon nitride layer covers the silicon oxide layer.

11. The stacked-gate non-volatile memory cell as claimed in claim 9, wherein the floating gate comprises a polysilicon gate layer.

12. The stacked-gate non-volatile memory cell as claimed in claim 9, wherein the control gate comprises a titanium nitride layer.

13. The stacked-gate non-volatile memory cell as claimed in claim 9, wherein the second spacer is a silicon nitride spacer.

14. The stacked-gate non-volatile memory cell as claimed in claim 9, wherein a width of the first spacer is in a range between 30 nm and 50 nm, and a width of the second spacer is in a range between 5 nm and 20 nm.

15. The stacked-gate non-volatile memory cell as claimed in claim 9, further comprising:
a first silicide layer contacted with the first doped region;
a second silicide layer contacted with the second doped region;
an insulation material layer covering the control gate and contacting with the second spacer; and
a contact etch stop layer covering and contacting with the insulation material layer, the second spacer, the first silicide layer and the second silicide layer.
